(19) United States
(12) Patent Application Publication
(10) Pub. No.: US 2007/0222063 A1
(43) Pub. Date: Sep. 27, 2007

(54) ELECTRONIC DEVICE CAPABLE OF VARYING APPEARANCE

(75) Inventor: Chien-Shih Hsu, Taipei City (TW)

Correspondence Address: QUINTERO LAW OFFICE, PC, 2210 MAIN STREET, SUITE 200, SANTA MONICA, CA, 90405, US

(73) Assignee: DARFON ELECTRONICS CORP., TAOYUAN (TW)

(21) Appl. No.: 11/688,231

(22) Filed: Mar. 19, 2007

(30) Foreign Application Priority Data
Mar. 22, 2006 (TW) TW95109876

(51) Int. Cl. H01L 23/12

(52) U.S. Cl. 257/704

(57) ABSTRACT

An electronic device capable of varying appearance includes a first cover, a second cover, and a third cover. The second cover is rotatably connected to the first cover. The third cover is movably connected to the first cover. The third cover is moved relative to the first cover from a retracted position to an extended position when the second cover is rotated relative to the first cover from a near position to a distant position. The third cover is moved relative to the first cover from the extended position to the retracted position when the second cover is rotated relative to the first cover from the distant position to the near position.

### BACKGROUND OF THE INVENTION

1. Field of the Invention

The invention relates to an electronic device, and more particularly to an electronic device capable of varying appearance to meet different operating conditions.

2. Description of the Related Art

Similar electronic devices may have different appearances suitable for different operating conditions. For example, computer mice for portable computers are small, facilitating transportation but disadvantageous to user's grasp. Thus, normal-sized computer mice are preferred for use. Similar problems arise in other electronic devices including multimedia players, personal digital assistants (PDAs), and portable phones.

Thus, an electronic device capable of varying appearance to meet various operating conditions including transportation, storage, use, and others is required.

### BRIEF SUMMARY OF THE INVENTION

To address the problem discussed, the invention provides an electronic device capable of varying appearance to meet different operating conditions.

The electronic device includes a first cover, a second cover, and a third cover. The second cover is rotatably connected to the first cover. The third cover is movably connected to the first cover. The third cover moved relative to the first cover from a retracted position to an extended position when the second cover is rotated relative to the first cover from a near position to a distant position. The third cover is moved relative to the first cover from the extended position to the retracted position when the second cover is rotated relative to the first cover from the distant position to the near position.

The electronic device may further include a linkage mechanism connecting the second cover and the third cover.

The linkage mechanism may include a connecting rod, and the connecting rod may include a first end pivoting on the second cover and a second end pivoting on the third cover.

The electronic device may further include a first shaft, a second shaft, and a third shaft. The second cover is rotatably connected to the first cover through the first shaft. The first end of the connecting rod pivots on the second cover through the second shaft. The second end of the connecting rod pivots on the third cover through the third shaft.

The first, second, and third shafts are at vertices of an obtuse triangle when the second cover is in the near position and the third cover is in the retracted position.

The first, second, and third shafts are at vertices of an acute triangle when the second cover is in the distant position and the third cover is in the extended position.

The second cover is supported by the connecting rod when the second cover is in the distant position and the third cover is in the extended position.

The third cover may include a first abutting surface, on which the connecting rod rests when the second cover is supported by the connecting rod.

The first shaft may be L-shaped.

The second shaft may be L-shaped.

The third shaft may be L-shaped.

The electronic device may further include a first spring pivoting on the first cover and the third cover.

The first spring may be a compression spring.

The first spring is rotated during movement of the third cover, and pushes the third cover toward the extended position after passing through an equilibrium position.

The electronic device may further include a second spring pivoting on the third cover and the connecting rod.

The second spring may be an expansion spring.

The second spring is rotated during movement of the third cover, and pushes the third cover toward the retracted position after passing through an equilibrium position.

The electronic device may include an input device.

The input device may include a computer mouse.

The electronic device may further include a receiver, wherein the third cover may have a storage space with the receiver removably disposed therein.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawings, wherein:

FIG. 1A depicts a computer mouse in a retracted state in accordance with an embodiment of the invention;

FIG. 1B depicts a computer mouse in an extended state in accordance with an embodiment of the invention;

FIG. 2 is an exploded perspective diagram of a computer mouse in accordance with an embodiment of the invention;

FIGS. 3A, 3B, and 3C depict a first cover, a second cover, a third cover, and a connecting rod of the computer mouse in accordance with an embodiment of the invention, varying between an extended state and a retracted state;

FIGS. 4A, 4B, and 4C depict a first spring of the computer mouse in accordance with an embodiment of the invention, during variation of the computer mouse between an extended state and a retracted state; and

FIGS. 5A, 5B, and 5C depict a second spring of the computer mouse in accordance with an embodiment of the invention, during variation of the computer mouse between an extended state and a retracted state.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

In the following descriptions, a computer mouse is described as an example for introducing the electronic device capable of varying appearance of the invention.

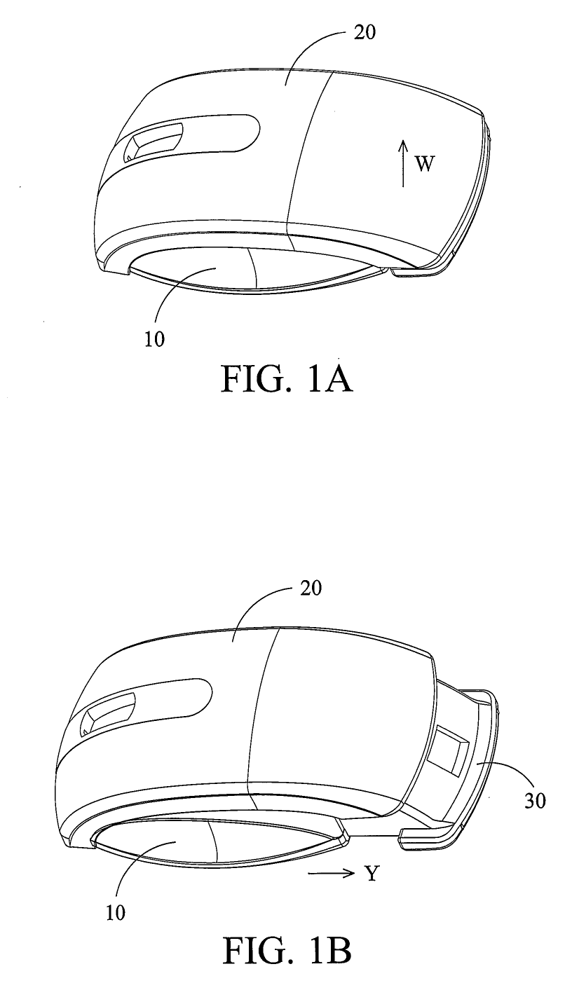

The appearance of the computer mouse can be changed between a retracted state and an extended state, wherein the computer mouse in the retracted state is suitable for storage and transportation and can be changed into the extended state to suit user's grasp. FIG. 1A depicts the computer mouse in the retracted state. To extend the computer mouse for use, the user grasps a first cover 10 of the computer mouse from the bottom with one hand and also grasps a second cover 20 from the top with the other hand. Then, the user raises the second cover 20 by applying a force W. As a result, the computer mouse is extended in height and length as shown in FIG. 1B, to suit user's grasp.

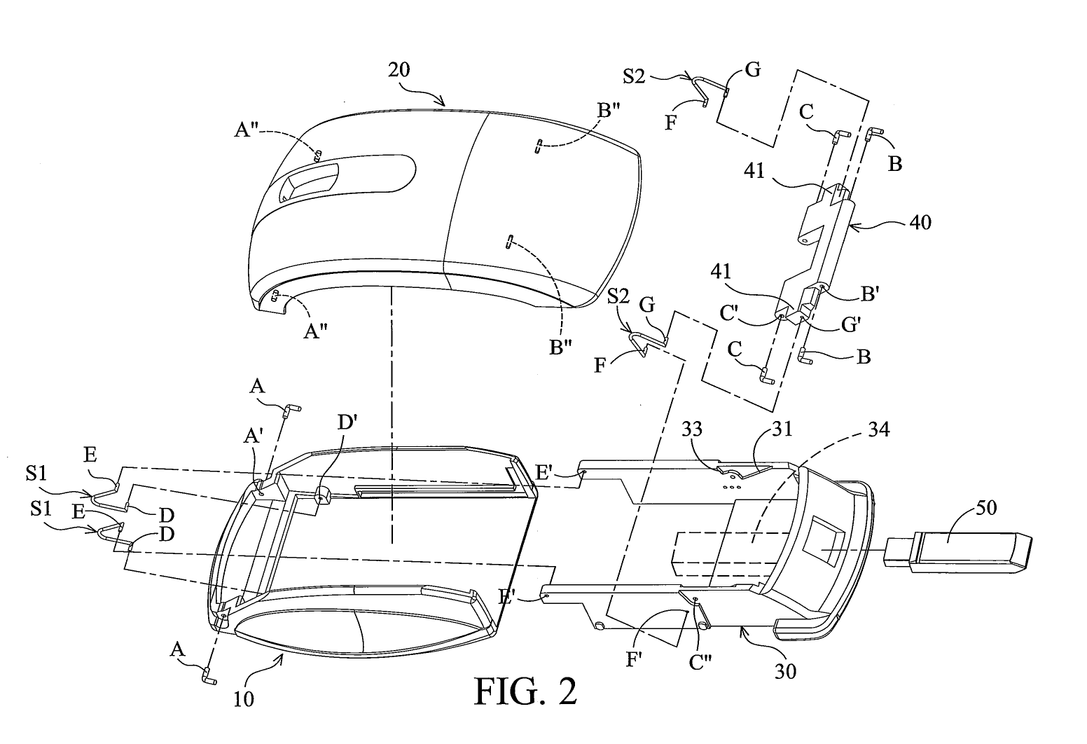

Referring to FIG. 2, the computer mouse includes a first cover 10, a second cover 20, a third cover 30, a linkage mechanism, and a receiver 50, wherein the linkage mechanism includes a connecting rod 40, at least a first spring S₁, and at least a second spring S₂. In this embodiment, however, a pair of first springs S₁ as well as a pair of second springs S₂ is provided on left and right sides of the computer mouse. The third cover 30 has a storage space 34 (indicated by broken lines). The receiver 50 is removably disposed in the storage space 34. In this embodiment, the computer mouse is a wireless mouse. When the receiver 50 is connected to a computer (not shown), wireless signals are transmitted from the wireless mouse through the receiver 50 to the computer.

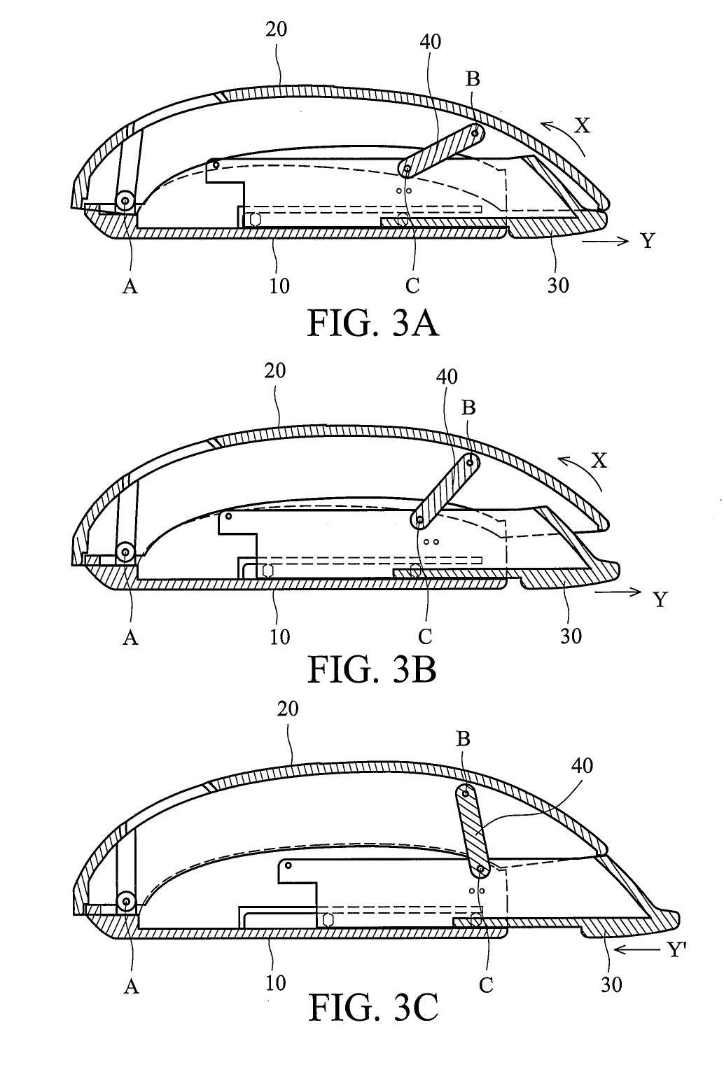

The second cover 20 pivots on the first cover 10 via first shafts A, wherein the first shafts A pass through the shaft holes A′ of the first cover 10 and the shaft holes A″ of the second cover 20. When the computer mouse is extended, as shown in FIGS. 3A, 3B, and 3C, the second cover 20 is rotated about the first shafts A in direction X related to the first cover 10, from a near position (FIG. 3A) to a distant position (FIG. 3C). As a result, the computer mouse is extended in height. In this embodiment, the first shafts A are L-shaped.

When the computer mouse is in the retracted state as shown in FIGS. 1A and 3A, most of the third cover 30 is hidden in the first cover 10 and covered with the second cover 20 from the top. When the computer mouse is extended, the third cover 30 is moved relative to the first cover 10 in direction Y, from the retracted position (FIG. 3A) to the extended position (FIG. 3C). As a result, the computer mouse is extended in length.

The connecting rod 40 pivots on the second cover 20 through second shafts B and on the third cover 30 through third shafts C. Referring to FIG. 2, in detail, the second shafts B pass through the shaft holes B′ of the first end of the connecting rod 40 and the shaft holes B″ of the second cover 20 whereby the first end of the connecting rod 40 pivots on the second cover 20. The third shafts C pass through the shaft holes C′ of the second end of the connecting rod 40 and the shaft holes C″ of the third cover 30 whereby the second end of the connecting rod 40 pivots on the third cover 30. In this embodiment, the second shafts B and the third shafts C are L-shaped.

In FIG. 3A, the second cover 20 is in the near position and the third cover 30 is in the retracted position. The first shaft A, the second shaft B, and the third shaft C are at the vertices of an obtuse triangle. In FIG. 3B, the second cover 20 and the third cover 30 are in the transitional positions. The first shaft A, the second shaft B, and the third shaft C are at the vertices of another obtuse triangle. In FIG. 3C, the second cover 20 is in the distant position and the third cover 30 is in the extended position. The first shaft A, the second shaft B, and the third shaft C are at the vertices of an acute triangle.

When the second cover 20 is raised, the third cover 30 is driven by the second cover 20 through the connecting rod 40, thus moving from the retracted position (FIG. 3A) to the transitional position (FIG. 3B). However, the movement of the third cover 30 from the transitional position (FIG. 3B) to the extended position (FIG. 3C) results from the restoring force of the first springs S₁, as follows:

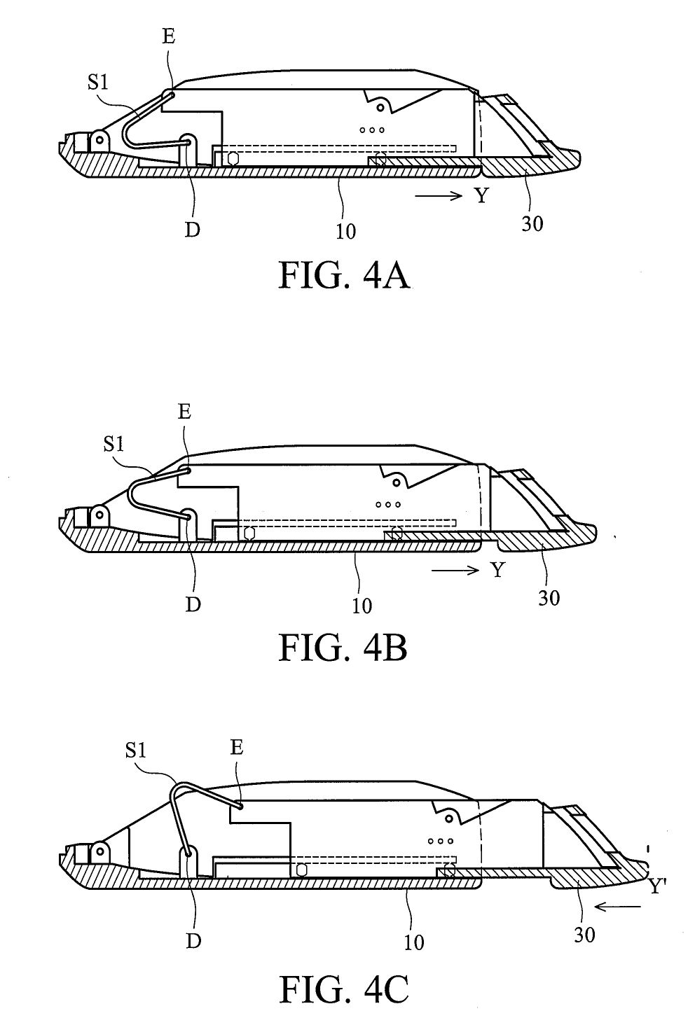

Referring to FIG. 2, in this embodiment, the first spring S₁ is a compression spring and has an end D passing through a hinge hole D′ of the first cover 10 and the other end E passing through a hinge hole E′ of the third cover 30. The operation and function of the first spring S₁ can be clearly described by reference to FIGS. 4A, 4B, and 4C. As described, the movement of the third cover 30 from the retracted position shown in FIG. 3A (corresponding to FIG. 4A) to the transitional position shown in FIG. 3B (corresponding to FIG. 4B) arises from the transmission of the connecting rod 40. Furthermore, the movement of the third cover 30 from the transitional position shown in FIG. 3B (corresponding to FIG. 4B) to the extended position shown in FIG. 3C (corresponding to FIG. 4C) arises from the restoring force of the first spring S₁. On comparison between FIGS. 4A, 4B, and 4C, it is understood that the movement of the third cover 30 causes the rotation of the first spring S₁. In FIG. 4B, the first spring S₁ is exactly at an equilibrium position and compressed to the most. Thus, upon passing through the equilibrium position, the first spring S₁ pushes the third cover 30 towards the extended position via the restoring force. Briefly, the third cover 30 is moved from the transitional position (FIG. 4B) to the extended position (FIG. 4C) by the first springs S₁.

To retract the computer mouse, the third cover 30 is pushed in direction Y′. Then, the third cover 30 is moved by the connecting rod 40 from the extended position (FIG. 3C) to the transitional position (FIG. 3B). However, the movement of the third cover 30 from the transitional position (FIG. 3B) to the retracted position (FIG. 3A) results from the restoring force of the second springs S₂, described in the following:

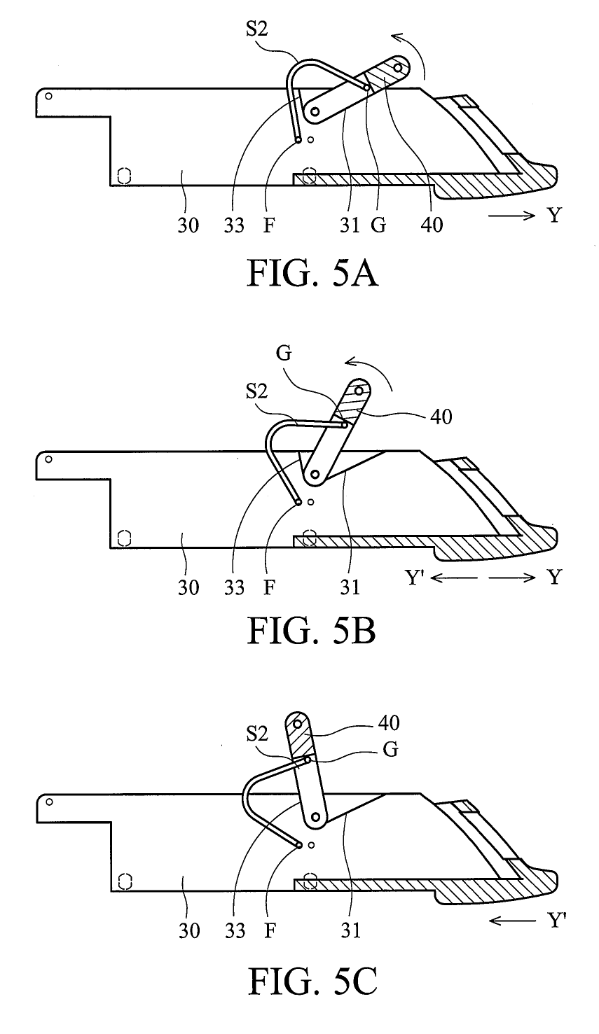

Referring to FIG. 2, in this embodiment, the second spring S₂ is an expansion spring and has an end F passing through a hinge hole F′ of the third cover 30 and the other end G passing through a hinge hole G′ of the connecting rod 40. The operation and function of the second spring S₂ can be clearly described by reference to FIGS. 5A, 5B, and 5C. As described, the movement of the third cover 30 from the extended position shown in FIG. 3C (corresponding to FIG. 5C) to the transitional position shown in FIG. 3B (corresponding to FIG. 5B) arises from the transmission of the connecting rod 40. Furthermore, the movement of the third cover 30 from the transitional position shown in FIG. 3B (corresponding to FIG. 5B) to the retracted position shown in FIG. 3A (corresponding to FIG. 5A) arises from the restoring force of the second spring S₂. On comparison between FIGS. 5A, 5B, and 5C, it is understood that the movement of the third cover 30 causes the rotation of the second spring S₂. In FIG. 5B, the second spring S₂ is exactly at an equilibrium position and expanded to a maximum. Thus, upon passing through the equilibrium position, the second spring S₂ pushes the third cover 30 towards the retracted position via the restoring force.

Referring to FIG. 2, the connecting rod 40 has contact portions 41 at both sides. The third cover 30 has a first abutting surface 33 and a second abutting surface 31 corresponding to each contact portion 41 of the connecting rod 40. As shown in FIG. 5A, the contact portion 41 of the connecting rod 40 rests on the second abutting surface 31 of the third cover 30 when the computer mouse is in the retracted state. As shown in FIG. 5C, the contact portion 41 of the connecting rod 40 rests on the first abutting surface 33 of the third cover 30 to support the second cover 20 when the computer mouse is in the extended state. The support of the connecting rod 40 prevents the second cover 20 from collapsing when the computer mouse is in user's grasp.

While a computer mouse is used for description of the disclosure in the descriptions, it is understood that the invention is equally applicable to a variety of electronic devices including input devices (e.g. keyboards), multimedia players, personal digital assistants (PDAs), and mobile phones.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An electronic device, comprising:
a first cover;
a second cover rotatably connected to the first cover; and
a third cover slidably connected to the first cover, wherein the third cover is moved relative to the first cover from a retracted position to an extended position when the second cover is rotated relative to the first cover from a near position to a distant position, and the third cover is moved relative to the first cover from the extended position to the retracted position when the second cover is rotated relative to the first cover from the distant position to the near position.

2. The electronic device as claimed in claim 1, further comprising a linkage mechanism connecting the second cover and the third cover.

3. The electronic device as claimed in claim 2, wherein the linkage mechanism comprises a connecting rod, and the connecting rod includes a first end pivoting on the second cover and a second end pivoting on the third cover.

4. The electronic device as claimed in claim 3, further comprising a first shaft, a second shaft, and a third shaft, the second cover rotatably connected to the first cover through the first shaft, the first end of the connecting rod pivoting on the second cover through the second shaft, and the second end of the connecting rod pivoting on the third cover through the third shaft.

5. The electronic device as claimed in claim 4, wherein the first, second, and third shafts are at vertices of an obtuse triangle when the second cover is in the near position and the third cover is in the retracted position.

6. The electronic device as claimed in claim 4, wherein the first, second, and third shafts are at vertices of an acute triangle when the second cover is in the distant position and the third cover is in the extended position.

7. The electronic device as claimed in claim 6, wherein the second cover is supported by the connecting rod when the second cover is in the distant position and the third cover is in the extended position.

8. The electronic device as claimed in claim 7, wherein the third cover comprises a first abutting surface, and the connecting rod rests on the first abutting surface when the second cover is supported by the connecting rod.

9. The electronic device as claimed in claim 4, wherein the first shaft is L-shaped.

10. The electronic device as claimed in claim 4, wherein the second shaft is L-shaped.

11. The electronic device as claimed in claim 4, wherein the third shaft is L-shaped.

12. The electronic device as claimed in claim 1, further comprising a first spring which pivots on the first cover and the third cover.

13. The electronic device as claimed in claim 12, wherein the first spring is a compression spring.

14. The electronic device as claimed in claim 13, wherein the first spring is rotated during movement of the third cover, and pushes the third cover toward the extended position after passing through an equilibrium position.

15. The electronic device as claimed in claim 3, further comprising a second spring which pivots on the third cover and the connecting rod.

16. The electronic device as claimed in claim 15, wherein the second spring is an expansion spring.

17. The electronic device as claimed in claim 16, wherein the second spring is rotated during movement of the third cover, and pushes the third cover toward the retracted position after passing through an equilibrium position.

18. The electronic device as claimed in claim 1, wherein the electronic device comprises an input device.

19. The electronic device as claimed in claim 18, wherein the input device comprises a computer mouse.

20. The electronic device as claimed in claim 1, further comprising a receiver, wherein the third cover has a storage space with the receiver removably disposed therein.
